(19) United States
(12) Patent Application Publication
(10) Pub. No.: US 2016/0002782 A1
(43) Pub. Date: Jan. 7, 2016

(54) Catalytic Atomic Layer Deposition Of Films Comprising SiOC

(71) Applicants: David Thompson, San Jose, CA (US); Jeffrey W. ANTHIS, San Jose, CA (US)

(72) Inventors: David Thompson, San Jose, CA (US); Jeffrey W. Anthis, San Jose, CA (US)

(21) Appl. No.: 14/769,722

(22) PCT Filed: Feb. 20, 2014
(86) PCT No.: PCT/US2014/017391

§ 371 Date: Aug. 21, 2015

Related U.S. Application Data
(60) Provisional application No. 61/767,860, filed on Feb. 22, 2013.

(51) Int. Cl. C23C 16/455; C23C 16/30

(52) U.S. Cl. CPC C23C 16/45534; C23C 16/30

(57) ABSTRACT

Provided are methods of for deposition of SiOC. Certain methods involve exposing a substrate surface to a first and second precursor in the presence of a catalyst comprising a neutral two electron donor base. The first precursor has formula (X_{y}H_{3-y}Si)_{z}CH_{4-z}, or (X_{y}H_{3-y}Si)(CH₂)ₙ(SiX_{y}H_{3-y}), wherein X is a halogen, y has a value of between 1 and 3, and z has a value of between 1 and 3, and n has a value between 2 and 5. The second precursor comprises water or a compound containing carbon and at least two hydroxyl groups. Certain other methods relate to exposing a substrate surface to a first and second precursor in the presence of a catalyst comprising a neutral two electron donor base, the first precursor comprising SiX₄ or X₃Si—SiX₃, wherein X is a halide, and the second precursor comprising carbon and at least two hydroxyl groups.

### TECHNICAL FIELD

The present invention relates generally to methods of depositing thin films. In particular, the invention relates to atomic layer deposition processes for the deposition of SiOC films.

### BACKGROUND

Deposition of thin films on a substrate surface is an important process in a variety of industries including semiconductor processing, diffusion barrier coatings and dielectrics for magnetic read/write heads. In the semiconductor industry, in particular, miniaturization requires atomic level control of thin film deposition to produce conformal coatings on high aspect structures. One method for deposition of thin films with control and conformal deposition is atomic layer deposition (ALD), which employs sequential, surface reactions to form layers of precise thickness. Most ALD processes are based on binary reaction sequences which deposit a binary compound film. Because the surface reactions are sequential, the two gas phase reactants are not in contact, and possible gas phase reactions that may form and deposit particles are limited.

ALD has been used to deposit metals and metal compounds on substrate surfaces. Al₂O₃ deposition is an example of a typical ALD process illustrating the sequential and self-limiting reactions characteristic of ALD. Al₂O₃ ALD conventionally uses trimethylaluminum (TMA, often referred to as reaction “A” or the “A” precursor) and H₂O (often referred to as the “B” reaction or the “B” precursor). In step A of the binary reaction, hydroxyl surface species react with vapor phase TMA to produce surface-bound AlOAl(CH₃)₂ and CH₄ in the gas phase. This reaction is self-limited by the number of reactive sites on the surface. In step B of the binary reaction, AlCH₃ of the surface-bound compound reacts with vapor phase H₂O to produce AlOH bound to the surface and CH₄ in the gas phase. This reaction is self-limited by the finite number of available reactive sites on surface-bound AlOAl(CH₃)₂. Subsequent cycles of A and B, purging gas phase reaction products and unreacted vapor phase precursors between reactions and between reaction cycles, produces Al₂O₃ growth in an essentially linear fashion to obtain the desired film thickness.

In order to facilitate deposition, catalysts have been used during some ALD processes. The catalyst is used to activate a reaction between two or more species during the deposition process. One process involving catalytic ALD involves the deposition of SiO₂ using water and SiCl₄. However, new catalytic ALD methods for other films are desired.

### SUMMARY

One aspect of the invention relates to a method of depositing a film. The method comprises exposing a substrate surface to a first and second precursor in the presence of a catalyst comprising a neutral two electron donor base, the first precursor having a formula (X_{y}H_{3-y}Si)_{z}CH_{4-z} or (X_{y}H_{3-y}Si)(CH₂)ₙ(SiX_{y}H_{3-y}), wherein X is a halogen, y has a value of between 1 and 3, and z has a value of between 1 and 3, and n has a value between 2 and 5, and the second precursor comprising water or a compound containing carbon and at least two hydroxyl groups. In one or more embodiments, each X is independently selected from Cl, Br and I.

In some embodiments, the first precursor has a formula (X_{y}H_{3-y}Si)_{z}CH_{4-z}. In further embodiments, the first precursor has a structure represented by:

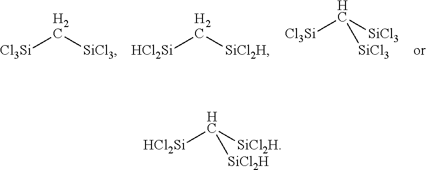

In some embodiments, the first precursor comprises bis(trichlorosilyl)methane. In one or more embodiments, the first precursor has a formula (X_{y}H_{3-y}Si)(CH₂)ₙ(SiX_{y}H_{3-y}). In further embodiments, n has a value of 2 or 3.

In some embodiments, the catalyst comprises an amine. In one or more embodiments, the catalyst comprises pyridine or NH₃. In some embodiments, the second precursor comprises a diol. In one or more embodiments, the diol comprises ethylene glycol, propylene glycol and butane-1,4-diol. In some embodiments, a film comprising SiOC is provided.

Another aspect of the invention relates to a method of depositing a film, the method comprising exposing a substrate surface to a first and second precursor in the presence of a catalyst comprising a neutral two electron donor base, the first precursor comprising SiX₄ or X₃Si—SiX₃, wherein X is a halide, and the second precursor comprises a compound containing carbon and at least two hydroxyl groups to provide a film comprising SiOC. In one or more embodiments, X is selected from the group consisting of Cl, Br and I.

In some embodiments, the first precursor comprising SiX₄. In one or more embodiments, the catalyst comprises an amine. In some embodiments, the catalyst comprises pyridine or NH₃. In one or more embodiments, the second precursor is a diol. In some embodiments, the diol comprises ethylene glycol, propylene glycol and butane-1,4-diol.

A third aspect of the invention relates to a method of depositing a film, the method comprising exposing a substrate surface to a first and second precursor in the presence of a catalyst comprising an pyridine, the first precursor comprising bis(trichlorosilyl)methane and the second precursor comprising water.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. shows an exemplary pulse sequence according to one or more embodiments of the invention;

FIG. 2 shows a depth profile of the elemental content of a film deposited according to one or more embodiments of the invention;

FIG. 3 shows a transmission electron microscope image of a film deposited according to one or more embodiments of the invention over a photoresist substrate;

FIG. 4 shows a transmission electron microscope image of a film deposited according to one or more embodiments of the invention over a silicon substrate; and

FIG. 5 shows a transmission electron microscope image of a film deposited according to one or more embodiments of the invention over blanket Si(100).

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways. It is also to be understood that the complexes and ligands of the present invention may be illustrated herein using structural formulas which have a particular stereochemistry. These illustrations are intended as examples only and are not to be construed as limiting the disclosed structure to any particular stereochemistry. Rather, the illustrated structures are intended to encompass all such complexes and ligands having the indicated chemical formula.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention any of the film processing steps disclosed may also be performed on an underlayer formed on the substrate as disclosed in more detail below, and the term “substrate surface” is intended to include such underlayer as the context indicates.

It has been discovered that SiOC films can be deposited using certain silicon precursors which contain a halogen and a second precursor selected from water or a diol. Either the diol or silicon precursor may contain carbon, which ends up incorporated into the film. Such SiOC films can exhibit better dielectric constants than the conventional SiO₂ films. Specifically, the carbon content can lower the dielectric constant, which lowers leakage at a transistor level.

Accordingly, one aspect of the invention relates to method of depositing a film. The method comprises exposing a substrate surface to a first and second precursor in the presence of a catalyst comprising a neutral two electron donor base, the first precursor having a formula (X_{y}H_{3-y}Si)_{z}CH_{4-z}, or (X_{y}H_{3-y}Si)(CH₂)ₙ(SiX_{y}H_{3-y}), wherein X is a halogen, y has a value of between 1 and 3, and z has a value of between 1 and 3, and n has a value between 2 and 5, and the second precursor comprising water or a compound containing carbon and at least two hydroxyl groups. In one or more embodiments, a film comprising SiOC is provided.

The first precursor is a silicon precursor, and can act as both a silicon and carbon source. In some embodiments, the first precursor has a formula (X_{y}H_{3-y}Si)_{z}CH_{4-z}. In one or more embodiments, each X is independently selected from Cl, Br and I. In further embodiments, embodiments at least one of the X groups is Cl. In even further embodiments, all X groups are Cl. Such a compound is known as bis(trichlorosilyl)methane, hexachlorodisilylmethylene, 1,1′-methylenebis(1,1,1-trichlorosilane), or methylenebis(trichlorosilane), and has a structure represented by:

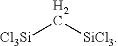

Other examples of suitable precursors include, but are not limited to those having a structure represented by:

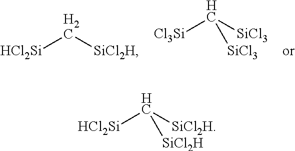

In other embodiments, the first precursor has a formula (X_{y}H_{3-y}Si)(CH₂)ₙ(SiX_{y}H_{3-y}). In further embodiments, n has a value of 2 or 3, or in even further embodiments, 2. Compounds of this formula may be used to further increase the carbon content, as the starting C:Si ratio will be higher. In one or more embodiments, each X is independently selected from Cl, Br and I. In further embodiments, embodiments at least one of the X groups is Cl. In even further embodiments, all X groups are Cl.

In some embodiments, the second precursor may comprise water. In embodiments where the second precursor comprises water, the resulting film will still contain carbon from the first precursor.

In other embodiments, the second precursor comprises a compound containing carbon and at least two hydroxyl groups. In further embodiments, the second precursor comprises a diol. In even further embodiments, diols may be used which contain carbon. In such embodiments, carbon incorporated into the film may come from both the first and second precursors. Suitable second precursors, include, but are not limited to, ethylene glycol, propylene glycol and butane-1,4-diol. In further embodiments, the diol comprises ethylene glycol. While not wishing to be bound to any particular theory, it is thought that at least two hydroxyl groups are necessary in order to allow for subsequent deposition cycles. That is, one OH group is used to deposit the second precursor, and then the second may be used for the next cycle to react with the Si—Cl in the first precursor. Films deposited using diols are thought to also have the advantage of being oxygen deficient.

Various first and second precursors can be selected to tune the amount of carbon in the deposited film. The higher the carbon:silicon ratio of the precursors, the higher the ratio will be in the resulting SiOC film. For example, in embodiments where the first precursor has formula (X_{y}H_{3-y}Si)(CH₂)ₙ(SiX_{y}H_{3-y}), longer carbon chains can be selected to result in a higher carbon content in the deposited film. In one or more embodiments, the carbon content of the film is about 10%.

The catalyst comprises a neutral two electron donor base. In one or more embodiments, the catalyst comprises an amine. In further embodiments, the catalyst comprises a tertiary amine. In further embodiments, the catalyst comprises pyridine. In other embodiments, the catalyst comprises NH₃. In embodiments relating to SiOC depositions at a temperature greater than 100° C., a tertiary amine with a vapor pressure lower than pyridine (which is less than about 20 torr at 20° C.) can be used.

In an exemplary embodiment, the method comprises exposing a substrate surface to a first and second precursor in the presence of a catalyst comprising an amine, the first precursor comprising bis(trichlorosilyl)methane and the second precursor comprising water. In further embodiments, the catalyst comprises pyridine. In one or more embodiments, a film comprising SiOC is provided.

Another aspect of the invention relates to a method of depositing a film, the method comprising a substrate surface to a first and second precursor in the presence of a catalyst comprising a neutral two electron donor base, the first precursor comprising SiX₄ or X₃Si—SiX₃, wherein X is a halide, and the second precursor comprising a compound containing carbon and at least two diols.

Again, the first precursor is a silicon precursor. In some embodiments, the first precursor comprises SiX₄. In other embodiments, the first precursor comprises X₃Si—SiX₃. In one or more embodiments, each X is independently selected from Cl, Br and I. In further embodiments, embodiments at least one of the X groups is Cl. In even further embodiments, all X groups are Cl. In embodiments where the first precursor comprises X₃Si—SiX₃, and all X groups are chlorine, the compound is Cl₃Si—SiCl₃, also known as hexachlorodisilane. Accordingly, in one or more embodiments, the silicon precursor is selected from SiCl₄, SiBr₄, or SiI₄.

The second precursor comprises carbon and at least two hydroxyl groups. Carbon may be incorporated into the deposited film from the second precursor. Accordingly, in one or more embodiments, the resulting film comprises SiOC. In some embodiments, the second precursor may comprise a diol. Suitable second precursors, include, but are not limited to, ethylene glycol, propylene glycol and butane-1,4-diol. In further embodiments, the diol comprises ethylene glycol. Again, as discussed above, it is thought that at least two OH groups are needed to repeat the cycle and get additional deposition.

The catalyst comprises a neutral two electron donor base. In one or more embodiments, the catalyst comprises an amine. In further embodiments, the catalyst comprises a tertiary amine. In further embodiments, the catalyst comprises pyridine. In other embodiments, the catalyst comprises NH₃. In embodiments relating to SiOC depositions at a temperature greater than 100° C., a tertiary amine with a vapor pressure lower than pyridine (which is less than about 20 torr at 20° C.) can be used.

The precursors may be flowed and/or exposed to the substrate surface either sequentially or substantially simultaneously. In embodiments where the substrate is exposed to the precursors sequentially, the process may be repeated up until a desired film thickness has been achieved. As used herein, “substantially simultaneously” refers to either co-flow or where there is merely overlap between exposures of the precursors. In one or more embodiments, the catalyst is added with any one or more of the reactants. In other embodiments, the catalyst is added alone, before and/or after any of the precursors.

The reaction conditions for the ALD reaction will be selected based on the properties of the film precursors, substrate surface, and the catalyst. The deposition may be carried out at atmospheric pressure, but may also be carried out at reduced pressure. The vapor pressure of the catalyst should be low enough to be practical in such applications. The substrate temperature should be low enough to keep the bonds of the substrate surface intact and to prevent thermal decomposition of gaseous reactants. However, the substrate temperature should also be high enough to keep the film precursors in the gaseous phase and to provide sufficient energy for surface reactions. The specific temperature depends on the specific substrate, film precursors, and catalyst used and pressure. The properties of the specific substrate, film precursors, and catalyst may be evaluated using methods known in the art, allowing selection of appropriate temperature and pressure for the reaction.

In one or more embodiments, the deposition is carried out at a temperature less than about 400, 350, 300, 250, 200, 150, 125, or 100° C. In some embodiments, the deposition is carried out at a temperature in the range of about 70 to about 100° C., about 70 to about 125° C. or about 70 to about 125° C.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyor system, in which multiple substrate are individually loaded into a first part of the chamber, move through the chamber and are unloaded from a second part of the chamber. The shape of the chamber and associated conveyor system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

### EXAMPLES

### Example 1

A SiOC was deposited using hexachlorodisilylmethylene and water using a pyridine catalyst. The pressure and temperature of the chamber were 12 torr and 70° C., respectively. The pulse sequence is shown in FIG. 1, which shows alternating pyridine/hexachlorodisilylmethylene pulses followed by alternating pyridine/water pulses. The hexachlorodisilylmethylene pulse length was 2.0 seconds, surrounded by a curtain of 1.0 second pyridine pulses. The water pulse length was 0.2 seconds, also surrounded by a curtain of 1.0 second pyridine pulses. Purge length was 10 seconds. The cycle was repeated 150 times to arrive at a film thickness of 16.7nm, corresponding to 1.1 Angstroms growth per cycle.

### Example 2

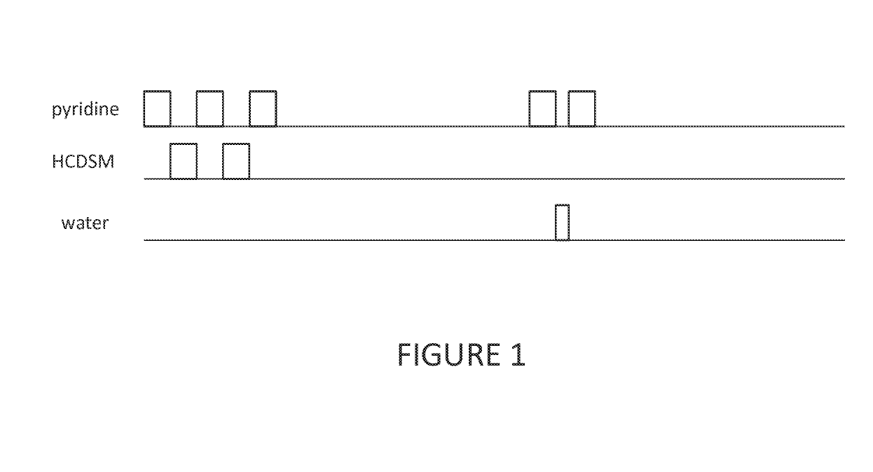

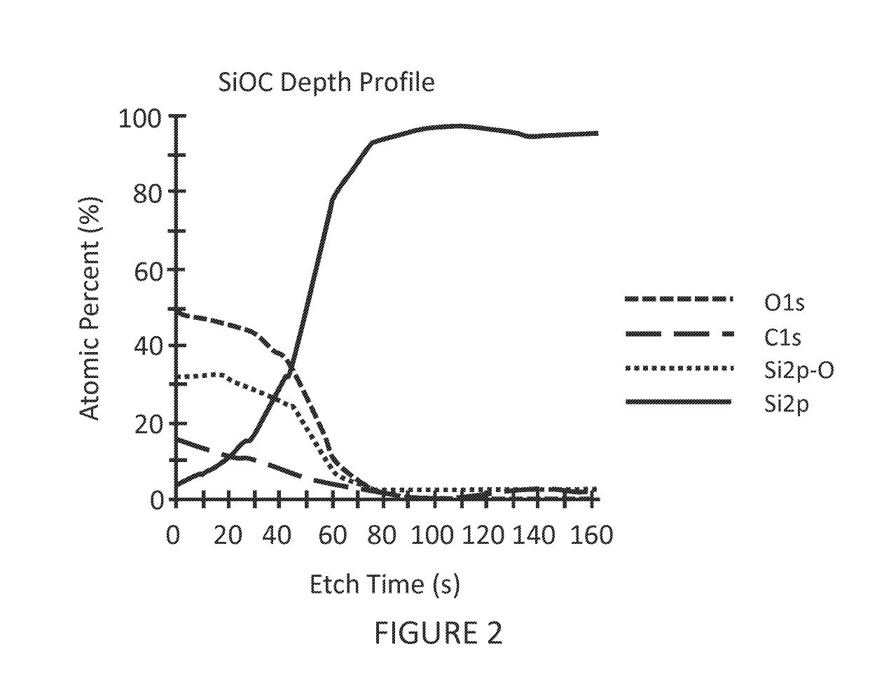

A SiOC was deposited using according to the methods of Example 1, except that the deposition was carried out to a film thickness of about 60-70 Angstroms. FIG. 2 shows the X-ray photoelectron spectroscopy depth profile of the SiOC film. Table 1 below shows the average elemental content in the bulk film.

TABLE 1
Average Content in Bulk Film

| O1s | C1s | Si2p-O/C | Si2p |
|---|---|---|---|
| 41.14 | 9.69 | 28.36 | 20.83 |

As seen from Table 1 and FIG. 2, no nitrogen or chlorine ends up deposited, showing that the precursor does not contaminate the film. The resulting carbon content was around 10%.

### Examples 3-5

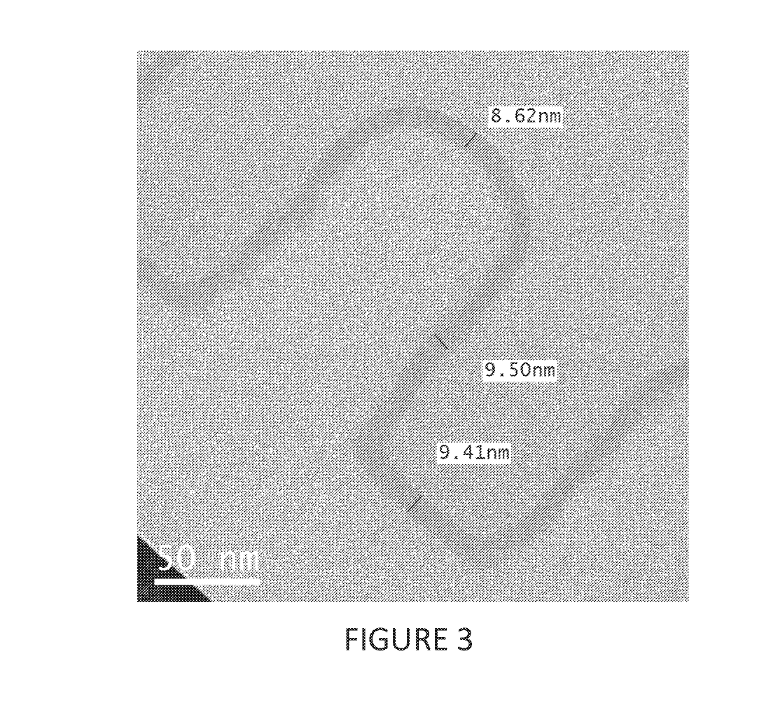

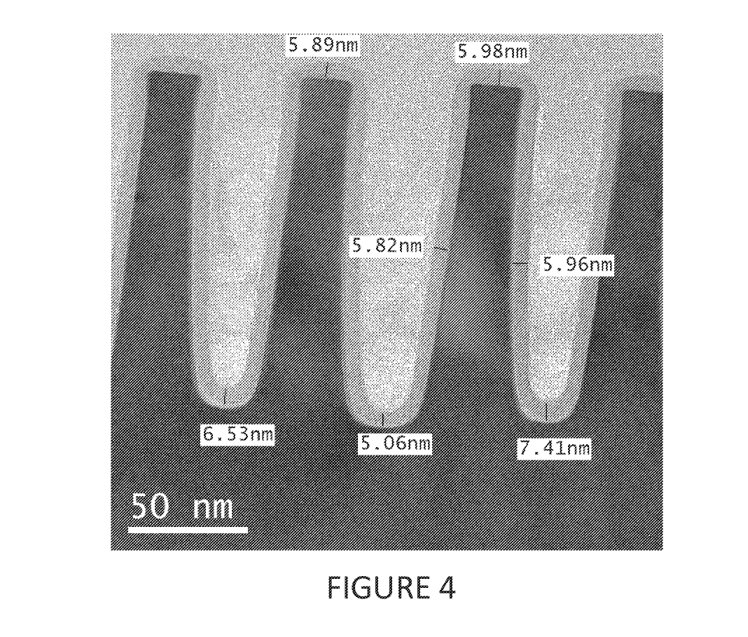

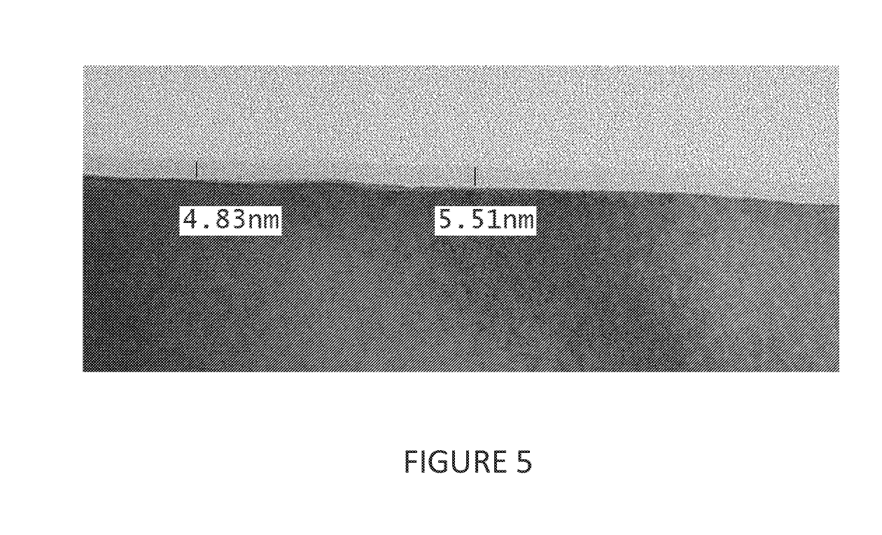

A SiOC was deposited using according to the methods of Example 1 over a photoresist, silicon substrate with features, and blanket Si(100). Transmission electron microscope photographs of the films were taken and are shown in FIGS. 3-5, respectively.

FIGS. 3-5 also show measurements of the film thickness at various points of the films. As can be seen in the photographs, the deposited films are very conformal over a variety of substrates, even over features in the substrate.

1-15. (canceled)

16. A method of depositing a film, the method comprising exposing a substrate surface to a first and second precursor in the presence of a catalyst comprising a neutral two electron donor base, the first precursor having a formula (X_{y}H_{3-y}Si)_{z}CH_{4-z} or (X_{y}H_{3-y}Si)(CH₂)ₙ(SiX_{y}H_{3-y}), wherein X is a halogen, y has a value of between 1 and 3, and z has a value of between 1 and 3, and n has a value between 2 and 5, and the second precursor comprising water or a compound containing carbon and at least two hydroxyl groups.

17. The method of claim 16, wherein each X is independently selected from Cl, Br and I.

18. The method of claim 16, wherein the first precursor has a formula (X_{y}H_{3-y}Si)_{z}CH_{4-z}.

19. The method of claim 18, wherein the first precursor has a structure represented by:

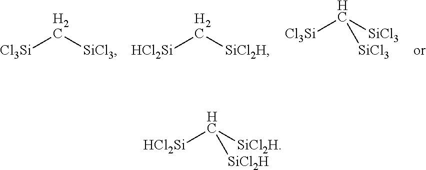

20. The method of claim 16, wherein the first precursor comprises bis(trichlorosilyl)methane.

21. The method of claim 16, wherein the first precursor has a formula (X_{y}H_{3-y}Si)(CH₂)ₙ(SiX_{y}H_{3-y}).

22. The method of claim 21, wherein n has a value of 2 or 3.

23. The method of claim 16, wherein the catalyst comprises an amine.

24. The method of claim 16, wherein the catalyst comprises pyridine or NH₃.

25. The method of claim 16, wherein the second precursor comprises a diol.

26. The method of claim 25, wherein the diol comprises ethylene glycol, propylene glycol and butane-1,4-diol.

27. The method of claim 16, wherein a film comprising SiOC is provided.

28. A method of depositing a film, the method comprising exposing a substrate surface to a first and second precursor in the presence of a catalyst comprising a neutral two electron donor base, the first precursor comprising SiX₄ or X₃Si—SiX₃, wherein X is a halide, and the second precursor comprises a compound containing carbon and at least two hydroxyl groups to provide a film comprising SiOC.

29. The method of claim 28, wherein X is selected from the group consisting of Cl, Br and I.

30. The method of claim 28, wherein the first precursor comprising SiX₄.

31. The method of claim 28, wherein the catalyst comprises an amine.

32. The method of claim 28, wherein the catalyst comprises pyridine or NH₃.

33. The method of claim 28, wherein the second precursor is a diol.

34. The method of claim 33, wherein the diol comprises ethylene glycol, propylene glycol and butane-1,4-diol.

35. A method of depositing a film, the method comprising exposing a substrate surface to a first and second precursor in the presence of a catalyst comprising an pyridine, the first precursor comprising bis(trichlorosilyl)methane and the second precursor comprising water.
